(19) United States
(12) Patent Application Publication
(10) Pub. No.: US 2007/0181958 A1
(43) Pub. Date: Aug. 9, 2007

(54) SEMICONDUCTOR DEVICE AND METHOD OF FORMING THE SAME

(75) Inventor: Hyuck-Chai JUNG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Suwon-si (KR)

(21) Appl. No.: 11/672,848

(22) Filed: Feb. 8, 2007

(30) Foreign Application Priority Data
Feb. 9, 2006 (KR) 2006-0012716

(51) Int. Cl. H01L 29/76

(52) U.S. Cl. 257/393

(57) ABSTRACT

A semiconductor device such as a Static Random Access Memory (SRAM) cell includes an access transistor. A drain of the access transistor includes a first N-type impurity and a second N-type impurity. The diffusion coefficient of the first N-type impurity is smaller than the diffusion coefficient of the second N-type impurity. By providing a drain as described above, hot carrier effects within the access transistor may be minimized.

### CROSS REFERENCE TO RELATED APPLICATIONS

This is application which claims the benefit of foreign priority to Korean Patent Application No. 2006-12716, filed on Feb. 9, 2006, the contents of which are hereby incorporated by reference in their entirety.

### BACKGROUND

1. Field of Invention

Embodiments of the present invention generally relate to semiconductor devices and methods of forming the same. More specifically, embodiments of the present invention relate to a semiconductor device such as a Static Random Access Memory (SRAM) cell and a method of forming the same.

2. Description of the Related Art

A unit cell of a conventional SRAM device has a flip-flop structure in which output ports of two inverters are cross-coupled. Such an SRAM cell can statically retain data due to flip-flop feedback effect while power is applied. Owing to these characteristics, SRAM devices have advantages such as lower power consumption and higher operating speed than DRAM devices. An SRAM cell includes a pair of driver transistors and a pair of load transistors, which constitute two inverters. Also the SRAM cell further includes two access transistors to externally select a cell.

As semiconductor devices continue to be scaled down, SRAM cells suffer from various problems such as, degradation of characteristics of access transistors constructed therein. This will now be described below with reference to FIG. 1.

FIG. 1 illustrates an equivalent circuit diagram of a conventional semiconductor device (e.g., an SRAM cell).

Referring to FIG. 1, a conventional SRAM cell includes an access and a driver transistor 10 and 15, respectively. The gate of the access transistor 10 is connected to word line (WL) 30, and a drain of the access transistor 10 is connected to bit line (BL) 25. A source of the access transistor 10 is connected to the driver transistor 25. Specifically, the source of the access transistor 10 is connected to the drain of driver transistor 15. The drain of the driver transistor 15 and the source of the access transistor 10 correspond to a node 20 for storing data. The source of the driver transistor 15 has access to ground line Vss.

In order to read the SRAM cell described above, a power supply voltage is applied to the bit line 25 and a turn-on voltage is applied to the word line 30 to turn on the access transistor 10. When “low” data is stored at the node 20, the access voltage decreases in the bit line 25. However, when “high” data is stored at the node 20, the voltage of the bit line 25 is maintained. The data stored in the SRAM cell may be decoded based upon the difference between voltages of the bit line 25.

As semiconductor devices continue to be scaled down, hot carrier effects may occur within the access transistor 10. When the “low” data is stored at the node 20, the driver transistor 15 is turned on, electrical current flows from the drain of access transistor 10 to the source of access transistor 10 and hot carrier effects occur around a boundary between the drain of access transistor 10 and channel region of access transistor 10, thereby depleting the access transistor 10.

A recent trend is to form gate electrodes having a narrow line width (e.g., on the order of tens of nanometers). Therefore, degradation of the access transistor 10 caused by hot carrier effects may increasingly occur. Also, short channel effects may become more severe to cause degradation of the characteristics of access transistor 10.

### SUMMARY

Exemplary embodiments of the present invention are directed to a semiconductor device and a method of fabricating the same.

One exemplary embodiment can be characterized as a semiconductor device that includes a substrate having an active region; a first impurity region and a second impurity region in the active region; an access gate insulating layer and an access gate electrode stacked on the active region between the first and second impurity regions; an interlayer dielectric on the access gate electrode; and a bit line on the interlayer dielectric and electrically connected to the first impurity region, wherein the first impurity region includes a first N-type impurity and a second N-type impurity, the second impurity region includes the first N-type impurity and a diffusion coefficient of the first N-type impurity is smaller than a diffusion coefficient of the second N-type impurity.

Another exemplary embodiment can be characterized as a method of forming a semiconductor device that includes forming an access gate insulating layer and access gate electrode on an active region of a substrate; forming a first impurity region and a second impurity region in the active region on either side of the access gate electrode; forming an interlayer dielectric on the access gate electrode; and forming a bit line on the interlayer dielectric, the bit line being electrically connected to the first impurity region, wherein the first impurity region includes a first N-type impurity and a second N-type impurity, the second impurity region includes the first N-type impurity, and a diffusion coefficient of the first N-type impurity is smaller than a diffusion coefficient of the second N-type impurity.

### BRIEF DESCRIPTION OF THE DRAWINGS

FIG. 1 illustrates an equivalent circuit diagram of a conventional semiconductor device;

FIG. 2 illustrates an equivalent circuit diagram of a semiconductor device according to an embodiment exemplarily described herein;

FIG. 3 illustrates a plan view of one embodiment of a semiconductor device;

FIG. 4 illustrates a cross-sectional view of the semiconductor device shown in FIG. 3, taken along line I-I′;

FIG. 5 is an enlargement of region “A” shown in FIG. 4;

FIGS. 6 to 9 illustrate cross-sectional views describing one embodiment of a method of forming the semiconductor device shown in FIG. 3, taken along line I-I-′; and

FIGS. 10 to 13 illustrate cross-sectional views to describing another embodiment of a method of forming the semiconductor device shown in FIG. 3, taken along line I-I′.

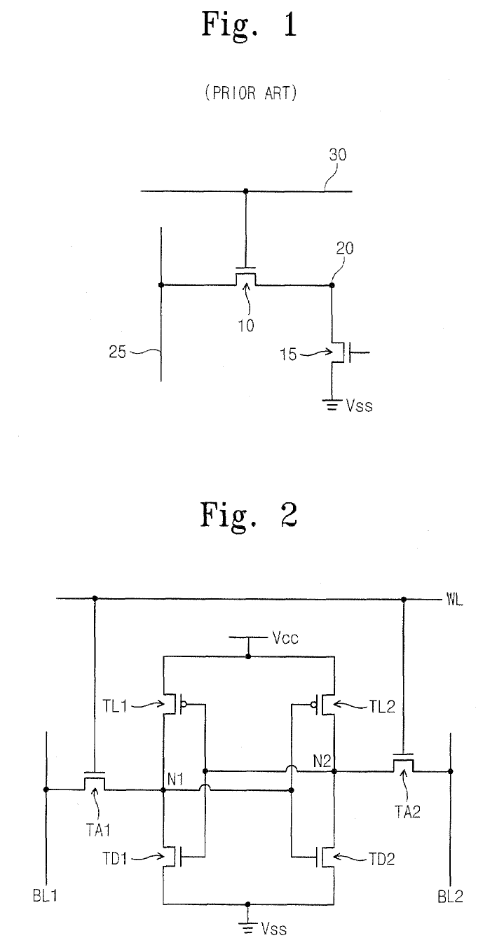

### DETAILED DESCRIPTION OF THE ILLUSTRATED EMBODIMENTS

According to embodiments exemplarily described herein, a semiconductor device (e.g., an SRAM cell) includes an active region defined at the substrate, first and second impurity regions formed on the active region and spaced from each other, an access gate insulating layer and an access gate electrode successively stacked on the active region between the first and the second impurity regions, a single-layered or a multi-layered interlayer dielectric covering the substrate, and a bit line connected to the contact plug penetrating the interlayer dielectric and electrically connected to the first impurity region, which is disposed on the interlayer dielectric. The first impurity region may contain a first N-type impurity and a second N-type impurity and the second impurity region may contain the first N-type impurity, wherein a diffusion coefficient of the first N-type impurity is smaller than a diffusion coefficient of the second N-type impurity.

According to embodiments exemplarily described herein, a method of forming semiconductor device (e.g., an SRAM cell) includes forming an access gate insulating layer and access gate electrode successively stacked on the active region defined at a substrate, forming a first impurity region and a second impurity region spaced apart from each other on either side of the access gate electrode, forming a single-layered or a multi-layered interlayer dielectric covering the substrate, and forming a bit line electrically connected to the first impurity region via contact plug penetrating the interlayer dielectric on the interlayer dielectric. The first impurity region may contain a first N-type impurity and a second N-type impurity and the second impurity region may contain the first N-type impurity, wherein a diffusion coefficient of the first N-type impurity is smaller than a diffusion coefficient of the second N-type impurity.

Exemplary embodiments of the present invention will now be described more fully hereinafter with reference to the accompanying drawings. These embodiments, however, may be realized in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like numbers refer to like elements throughout.

FIG. 2 illustrates an equivalent circuit diagram of one embodiment of a semiconductor device (e.g., an SRAM cell).

Referring to FIG. 2, a semiconductor device such as an SRAM cell may, for example, include first and second access transistors TA1 and TA2, respectively, first and second driver transistors TD1 and TD2, respectively, and first and second load transistors TL1 and TL2, respectively. The access and driver transistors TA1, TA2, TD1 and TD2 are all NMOS transistors. In one embodiment, the load transistors TL1 and TL2 are PMIS transistors. In another embodiment, the load transistors TL1 and TL2 may be replaced by load resistors.

The first driver transistor TD1 and the first access transistor TA1 are connected to each other in series. In other words, the drain of the first driver transistor TD1 is connected to the source of the first access transistor TA1. The drain of the first access transistor TA1 is connected to a first bit line BL1 and the source of the first driver transistor TD1 is connected to the ground line Vss. Similarly, drain of the second driver transistor TD2 is connected to the source of the second access transistor TA2 and the second bit line BL2 is connected to the drain of the second access transistor TA2. The source of the second driver transistor TD2 is connected to the ground line Vss.

The source and drain of the first load transistor TL1 are connected to power line Vcc and drain of the first driver transistor TD1, respectively, and the source and drain of the second load transistor TL2 are connected to the power line Vcc and drain of the second driver transistor TD2, respectively. The gate of the first driver transistor TD1 and gate of the first load transistor TL1 are electrically connected to each other. Also, the gate of the second driver transistor TD2 and gate of the second load transistor TL2 are electrically connected to each other.

The drain of the first load transistor TL1, the drain of the first driver transistor TD1 and the source of the first access transistor TA1 are electrically connected together at (i.e., correspond to) the first node N1. Similarly, the drain of the second load transistor TL2, the drain of the second driver transistor TD2 and the source of the second access transistor TA2 correspond to the second node N2.

The first load transistor TL1 and the first driver transistor TD1 comprise a first inverter, and the second load transistor TL2 and the second driver transistor TL2 comprises a second inverter. Gates of the first load and driver transistors TL1 and TD1 correspond to the input element of the first inverter while the first node N1 corresponds to output element of the first inverter. Similarly, gates of the second load and driver transistors TL2 and TD2 correspond to the input element of the second inverter while the second node N2 corresponds to output element of the second inverter. The first load and driver transistors TL1 and TD1 are connected to the second node N2, and the second load and driver transistors TL2 and TD2 are connected to the first node N1. Constructed as described above, the first and second inverters have a flip-flop structure. Further, gates of the first and second access transistors TA1 and TA2 are connected to the word line WL.

As illustrated in FIG. 2, the semiconductor device includes an access transistor and a driver transistor. The access and driver transistors will be described in greater detail below.

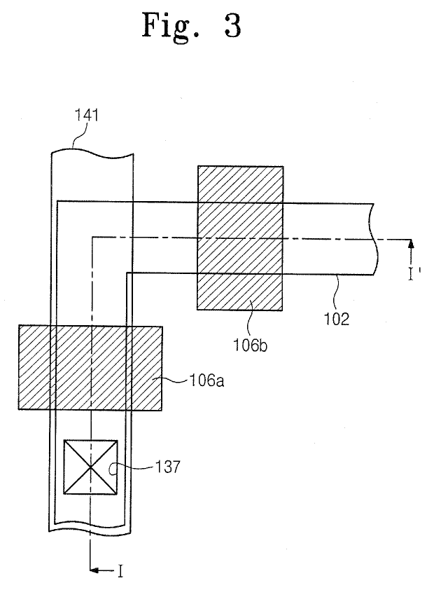

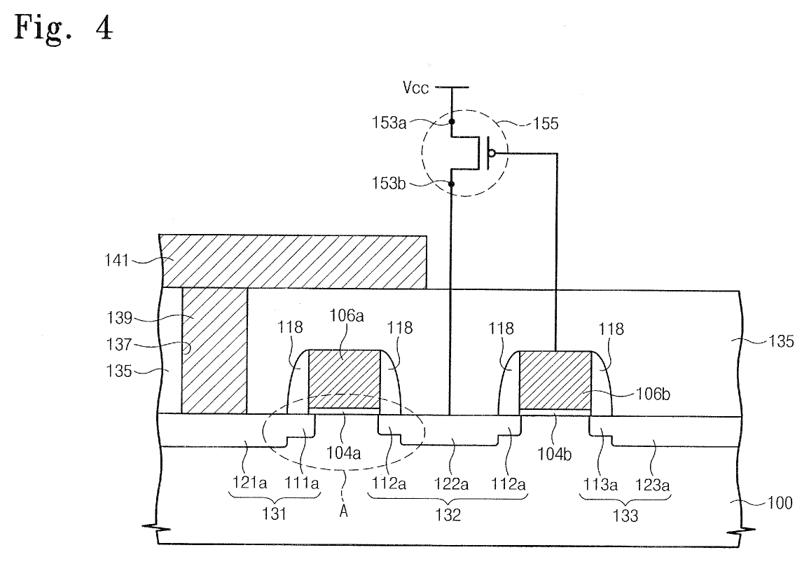

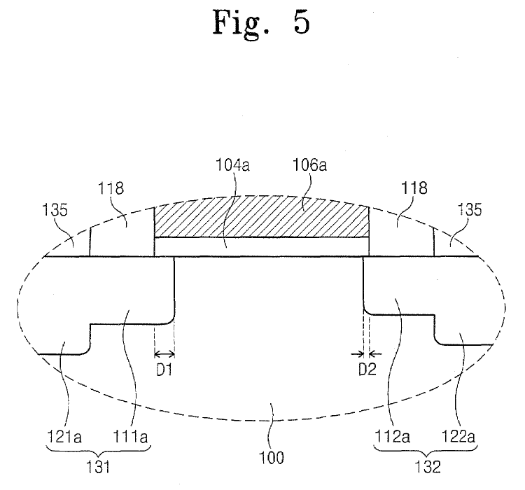

FIG. 3 illustrates a plan view of one embodiment of a semiconductor device, FIG. 4 illustrates a cross-sectional view of the semiconductor device shown in FIG. 3, taken along line I-I′, and FIG. 5 is an enlargement of region “A” shown in FIG. 4.

Referring to FIGS. 3 to 5, an interlayer dielectric is disposed on semiconductor substrate 100, substrate hereafter to define active region 102. In the illustrated embodiment shown in FIG. 3, the active region 102 may be provided in an angular form. In another embodiment, the active region 102 may be provided in any suitable form. The active region 102 is doped with a P-type impurity (e.g., P-type impurity ions).

First and second impurity regions 131 and 132 are formed in the active region 102 and are spaced apart from each other (e.g., separated from each other by a portion of the active region). An access gate interlayer dielectric 104a and access gate electrode 106a are successively stacked in the active region 102 between the first and second impurity regions 131 and 132. An access channel region is defined under the access gate electrode 106a and is disposed between the first and second impurity regions 131 and 132. The access gate electrode 106a and the first and second impurity regions 131 and 132 comprise access transistor. The first impurity region 131 corresponds to drain of the access transistor, and the second impurity region 132 is operably proximate to the access gate electrode 106a to function as a source of the access transistor. The first and/or second access transistor TA1 and/or TA1 shown in FIG. 2 may be provided as the access transistor shown in FIG. 4.

A third impurity region 133 is spaced apart from the second impurity region 132 within the active region 102. A driver gate insulating layer 104b and driver gate electrode 106b are successively stacked in the active region 102 between the second impurity region 132 and the third impurity region 133. A driver channel region is defined under the driver gate electrode 106b and is disposed between the second impurity region 132 and the third impurity region 133. The second impurity region 132 is formed in the active region 102 between the access gate electrode 106a and driver gate electrode 106b. The access and driver gate electrodes 106a and 106b are spaced apart from each other. The access and driver gate electrodes 106a and 106b are disposed in the active region 102 between the first impurity region 131 and the third impurity region 133. The driver gate electrode 106b and the second and third impurity regions 132 and 133 compose driver transistor. The second impurity region 132 is operably proximate to the driver gate electrode 106b to function as a drain of the driver transistor and the third impurity region 133 corresponds to the source of the driver transistor. In the illustrated embodiment, the access transistor and the driver transistor share the second impurity region 132. The first and/or second nodes N1 and/or N2 shown in FIG. 2 may be provided as the second impurity region 132 shown in FIG. 4.

The first impurity region 131 includes a first N-type impurity and a second N-type impurity while the second impurity region 132 includes the first N-type impurity. In one embodiment, a diffusion coefficient of the first N-type impurity is smaller than a diffusion coefficient of the second N-type impurity. For example, the first N-type impurity may include arsenic (As) and the second N-type impurity may include phosphorus (P).

Gate spacers 118 are disposed on both sidewalls of the access gate electrode 106a and the driver gate electrode 106b. The first impurity region 131 may include a first low-concentration region 111a and a first high-concentration region 121a. The first low-concentration region 111a is disposed between the access channel region and the first high-concentration region 121a. The first low-concentration region 111a may be disposed under the gate spacer 118. The impurity concentration of the first N-type impurity within the first high-concentration region 121a is higher than the impurity concentration of the N-type impurity within the first low-concentration region 111a. In one embodiment, the first low-concentration and high-concentration regions 111a and 121a include the second N-type impurity. In one embodiment, the first impurity region 131 may include only the first low-concentration region 111a. In this case, the first low-concentration region 111a may extend next to the active region where the first high-concentration region 121a is formed.

The second impurity region 132 may include a second low-concentration region 112a and a second high-concentration region 122a. The second low-concentration region I 12a may be disposed between the access channel region and the second high-concentration region 122a, and between the driver channel region and the second high-concentration region 122a. The third impurity region 133 may include a third low-concentration region 113a and a third high-concentration region 123a. The third low-concentration region 113a may be disposed between the driver channel region and the third high-concentration region 123a. In one embodiment, the second and/or third high-concentration regions 122a and 123a may be omitted. In this case, respective ones of the second and/or third low-concentration regions 112a and 11 3a may each extend next to the active region where the second and third high-concentration regions 122a and 123a are formed.

An interlayer dielectric 135 covers the entire surface of the substrate 100. The interlayer dielectric 135 may be provided as a single layer of dielectric material or as a structure comprising multiple layers of dielectric material. A contact plug 139 fills a contact hole 137 defined within the interlayer dielectric 135. The contact plug 139 contacts the first impurity region 131. A bit line 141 is disposed on the interlayer dielectric 135. The bit line 141 is connected to the contact plug 139. Accordingly, the bit line 141 is electrically connected to the first impurity region 131 through the contact plug 139.

A load transistor 155 is disposed on the substrate 100. The load transistor 155 includes the first and second source/drain regions 153a and 153b, respectively. The first source/drain region 153a is connected to the power line (Vcc) and the second source/drain region 153b is electrically connected to the second impurity region 132. A gate of the load transistor 155 is electrically connected to the driver gate electrode 106b. The load transistor 155 is defined on the substrate 100 and may be formed in the second impurity region 132. Generally, the load transistor 155 may be disposed over the access and/or driver gate electrodes 106a and 106b. In this case, the first and second source/drain regions 153a and 153b of the load transistor 155 may be formed on the substrate 100 (e.g., a semiconductor single crystalline layer formed by epitaxial method or solid phase epitaxial method). Also, the load transistor 155 may be formed at a level below the bit line 141. In this case, interlayer dielectric 135 may be comprised of multiple layers (i.e., levels).

As described above, the first N-type impurity has a relatively small diffusion coefficient. Therefore, the first N-type impurity has a short diffusion distance in the presence of heat. Accordingly, an increase in volume of the second and third impurity regions 132 and 133 due to diffusion can be minimized because the second and third impurity regions 132 and 133 only contain the first N-type impurity. Also, an impurity concentration profile of the junction of the second and third impurity regions 132 and 133 may have a relatively distinct boundary. As a result, short channel effects within the driver transistor may be minimized using the second and third impurity regions 132 and 133 respectively as a drain or source. Also, short channel effects within the access transistor may be minimized using the second impurity region 132 as a source.

As described above, the second N-type impurity has a relatively large diffusion coefficient. Therefore, the second N-type impurity has a longer diffusion distance than the first N-type impurity in the presence of heat. Accordingly, an increase in volume of the first impurity region 131 is higher than that of the second impurity region 132 because the first impurity region 131 also contains the second N-type impurity. Therefore, a first width D1 overlapping one portion of the first impurity region 131 and the access gate electrode 106a is larger than a second width D2 overlapping another portion of the second impurity region 131 and the access gate electrode 106a. In other words, the area of overlap between the first impurity region 131 and the access gate electrode 106a is larger than the area of overlap between the second impurity region 132 and the access gate electrode 106a. As a result, the electric field generated by a turn-on voltage applied to the access gate electrode 106a by a word line WL may act to offset a portion of electric field generated by a power voltage applied to the first impurity region 131 by the bit line 141 when the semiconductor device shown in FIGS. 3-5 is decoded. Consequently, a hot carrier effect generated in a first junction at the edge of the first impurity region 131 and the access channel region may be decreased. Also, because the first impurity region 131 contains the first N-type impurity, the volume increase of the first impurity region 131 can be limited. In addition, the short channel effect may also be decreased.

If the first impurity region 131 includes only the second N-type impurity, the volume increase of the first impurity region 131 due to diffusion may become excessive, thereby increasing the short channel effect of the access transistor. As disclosed above, however, the first impurity region 131 includes both the first N-type impurity and the second N-type impurity. Thus, the volume increase resulting from diffusion of the first impurity region 131 may be limited.

When decoding the semiconductor device, electric current does not flow from the second impurity region 132 (i.e., a node) to the first impurity region 131, which is connected to bit line 141. Therefore, the second junction in the edge of the second impurity region 132 and the access channel region may be free from hot carrier effect. Even though the second impurity region 132 is overlapped by the access gate electrode 106a, the characteristics of the access transistor do not deteriorate. In fact, as the overlapping area between the second impurity region 132 and the access gate electrode 106a decreases, the length of the access channel region increases, thereby decreasing the short channel effect of the access transistor.

As disclosed above, the second and third impurity regions 132 and 133 include only the first N-type impurity. In one embodiment, the overlapping area of the second impurity region 132 and the driver gate electrode 106b, and the overlapping area of the third impurity region 133 and the driver gate electrode 106b may be substantially equal to the overlapping area of the second impurity region 132 and the access gate electrode 106a.

In addition, because the second N-type impurity has a relatively large diffusion coefficient, the impurity concentration profile of the first impurity region 131 adjacent to the first junction becomes broader compared to the impurity concentration profile of the second impurity region 132 adjacent to the second junction. The impurity concentration of the first impurity region 131 adjacent to the first junction (e.g., the impurity concentration including both the first and second N-type impurities) becomes lower than the impurity concentration of the second impurity region 132 adjacent to the second junction. When decoding, electric field in the first junction is decreased. Accordingly, generation of the hot carrier effect may be minimized within the first junction. A concentration of the second N-type impurity within a portion of the first impurity region 1 31 of the first junction may be higher than a concentration of the first N-type impurity within the portion of the first impurity region 131 of the first junction. Also, as the impurity concentration of the first impurity region 131 in the first junction decreases, the junction capacitance of the first impurity region 131 decreases. The junction capacitance of the first impurity region 131 may operate as the parasitic capacitance. As the junction capacitance of the first impurity region 131 decreases, the parasitic capacitance of the bit line 141 may be decreased. As a result, the operation speed of the semiconductor device may be enhanced.

In view of the above, the first impurity region 131 of the access transistor can be susceptible to deterioration due to the hot carrier effect. When the first impurity region 131 includes the first and second N-type impurities, however, both the hot carrier effect and short channel effect of the access transistor may be decreased. Also, the second impurity region 132 and the third impurity region 133, which are free of the hot carrier effects, include only the first N-type impurity to minimize the short channel effect of the access and driver transistors. Therefore, the semiconductor device described above with respect to FIGS. 2 to 5 may be highly integrated such that the access transistor and driver transistor have optimized characteristics.

The aforementioned first and second access transistors TA1 and TA2 may be the in same form as the access transistor explained with regard to FIGS. 3 to 5. The first and second access transistors TA1 and TA2 may be formed along a common axis. The aforementioned first and second driver transistors TD1 and TD2 may be symmetrically formed as the driver transistor explained with regard to FIGS. 3 to 5. Accordingly, the first and second driver transistors TD1 and TD2 may be symmetrical with respect to each other.

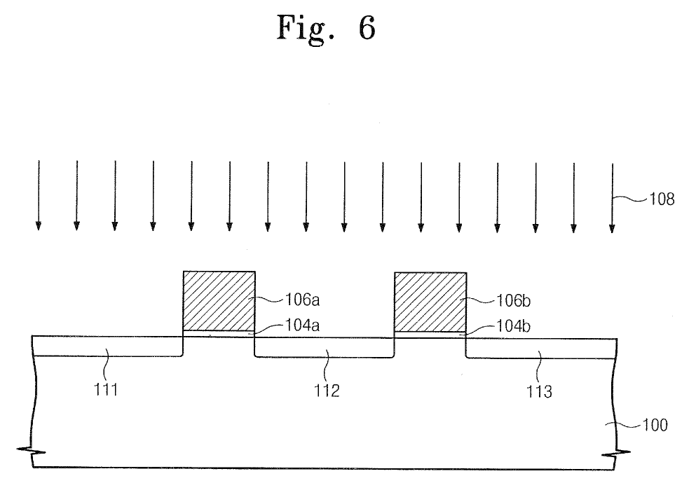

FIGS. 6 to 9 illustrate cross-sectional views describing one embodiment of a method of forming the semiconductor device shown in FIG. 3, taken along line I-I′.

Referring to FIG. 6, an active region is defined by forming a device isolation layer (not shown) on the substrate 100. The access gate insulation layer 104a and driver gate electrode 106b, successively stacked, and driver gate insulating layer 104b and driver gate electrode 106b, successively stacked, are formed in the active region. The access gate electrode 106a and driver gate electrode 106b are formed to be spaced apart from each other. The access and driver gate insulating layers 104a and 104b may include the same material. For example, the access and driver gate insulation layers 104a and 104b may include silicon oxide (e.g., thermal oxide). The access and driver gate electrodes 106a and 106b may include the same material. For example, the access and driver gate electrodes 106a and 106b may include a conductive material including at least one selected from the group consisting of doped poly-silicon, metal (e.g., tungsten, molybdenum, etc.), conductive metal nitrade (e.g., titanium nitride, tantalum nitride, etc.), metal silicide (e.g., tungsten silicide, cobalt silicide, etc.), or the like.

A first ion implant 108 is performed using the access and driver gate electrodes 106a and 106b as an implantation mask to implant a first dose of first N-type impurity (e.g., first impurity ions) into the active region. As a result, a preliminary first low-concentration implant region 111, a second low-concentration implant region 112 and a third low-concentration implant region 113 are formed in the active region. The preliminary first low-concentration implant region 111 is formed in the active region on one side of the access gate electrode 106a, the second low-concentration implant region 112 is formed in the active region between the access and driver gate electrodes 106a and 106b, and the third low-concentration implant region 113 is formed in the active region on one side of the driver gate electrode 106b. The access and driver gate electrodes 106a and 106b are disposed in the active region between the preliminary first low-concentration implant region 111 and the third low-concentration implant region 113.

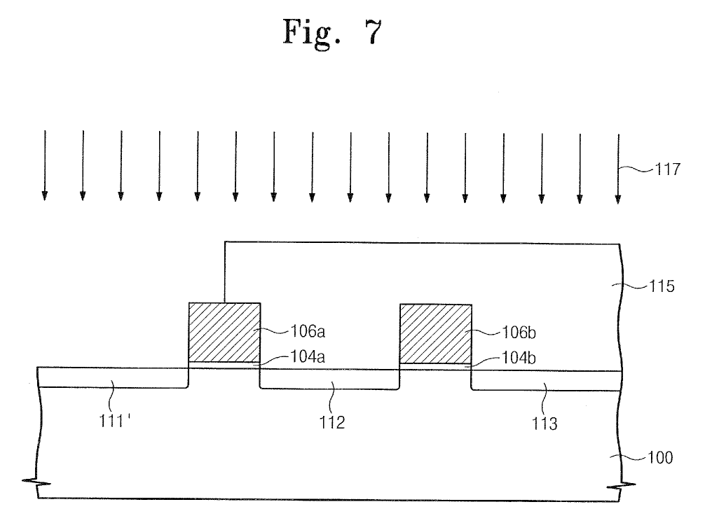

Referring to FIG. 7, a mask pattern 115 is formed on the substrate 100. The mask pattern 115 covers the second and third low-concentration implant regions 112 and 113 and exposes the preliminary first low-concentration injection region 111. The mask pattern 115 may cover the driver gate electrode 106b. Also, the mask pattern 115 may cover a portion of the access gate electrode 106a. The mask pattern 115 may include a photosensitive material.

Next, a second ion implant 117 is performed using the mask pattern 115 as an implantation mask to implant the second N-type impurity (e.g., second impurity ions) into the active region. As a result, a first low-concentration implant region 111 is formed from the preliminary first low-concentration implant region 111 such that the first low-concentration implant region 111′ contains both the first N-type impurity and the second N-type impurity. In one embodiment, the diffusion coefficient of the first N-type impurity is smaller than the diffusion coefficient of the second N-type impurity. For example, the first N-type impurity may include arsenic (As) and the second N-type impurity may include phosphorus (P).

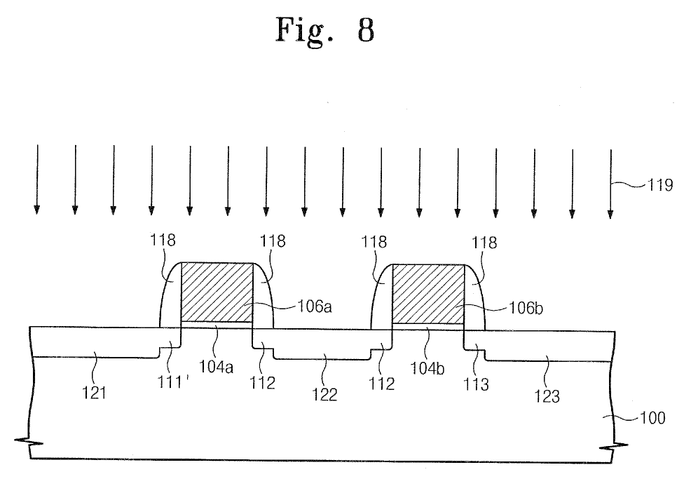

Referring to FIG. 8, the mask pattern 115 is removed from the substrate 100. Gate spacers 118 are formed on both sidewalls of the access and driver gate electrodes 106a and 106b. Gate spacer 118 may include insulating material such as silicon nitride, silicon oxide, silicon oxide nitride, or the like.

Next, a third ion implant 119 is performed using the access and driver gate electrodes 106a and 106b and gate spacers 118 as an implantation mask to implant a second dose of the first N-type impurity (e.g., first impurity ions) into the active region. The concentration of first N-type impurity within the second dose may be higher than that of the aforementioned first dose. As a result, first, second and third high-concentration implant regions 121, 122 and 123, respectively, are formed in the first, second and third low-concentration implant regions 111′, 112 and 113, respectively. In one embodiment, the third ion implant 119 may be omitted if desired.

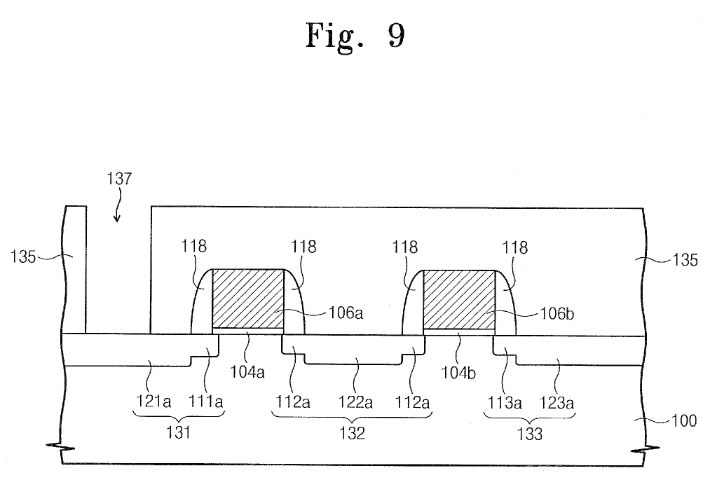

Referring to FIG. 9, an impurity activation process is performed to activate the impurity ions implanted into the active region. The impurity activation process may be performed after the low-concentration implant regions 111′, 112 and 113 and the high-concentration implant regions 121, 122 and 123 have been formed. In the event that the third ion implant 119 is omitted, a gate oxidation process performed after the low-concentration implant regions 111′, 112 and 113 are formed may be used as the impurity activation process.

Upon performing the impurity activation process, the first impurity region 131, which includes the first low-concentration and high-concentration regions 111a and 121a, the second impurity region 132, which includes the second low-concentration and high-concentration regions 112a and 122a, and the third impurity region 133, which includes the third low-concentration and high-concentration regions 113a and 123a, are all formed. In the event that the third ion implant 119 is omitted, the first, second and third impurity regions 131, 132 and 133 may include only the first, second and third low-concentration regions 111a, 112a and 113a, respectively.

The first impurity region 131 includes the first and second N-type impurities and the second and third impurity regions 132 and 133 include the first N-type impurity only.

Next, the interlayer dielectric 135 covering the substrate 100 is formed. The interlayer dielectric 135 may include a single layer or a structure comprising multiple layers. The interlayer dielectric 135 may, for example, include one or more layers of insulating material such as silicon oxide, or the like.

The interlayer dielectric 135 is then patterned to form a contact hole 137 exposing the first impurity region 131. Next, a contact plug 139 is formed to fill the contact hole 137 as shown in FIG. 4. Subsequently, bit lines 141 such as those shown in FIGS. 3 and 4 are formed on the interlayer dielectric 135 to contact the contact plug 139. Accordingly, the bit line 141 is electrically connected to the first impurity region 131 via the contact plug 139 and the semiconductor device illustrated in FIGS. 3 to 5 is formed.

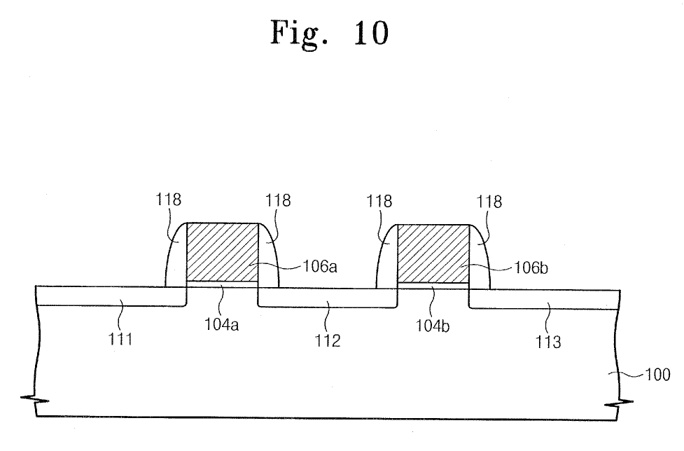

As described above, FIGS. 7 to 9 illustrate one exemplary method of forming the first impurity region 131. Another exemplary method of forming the first impurity region 131 will now be discussed with respect to FIGS. 10 to 13.

After forming the aforementioned preliminary first low-concentration implant region 111, second low-concentration implant region 112 and third low-concentration implant region 113 as shown in FIG. 6, gate spacers 118 are formed on both sidewalls of the access gate electrode 106a and driver gate electrode 106b as shown in FIG. 10.

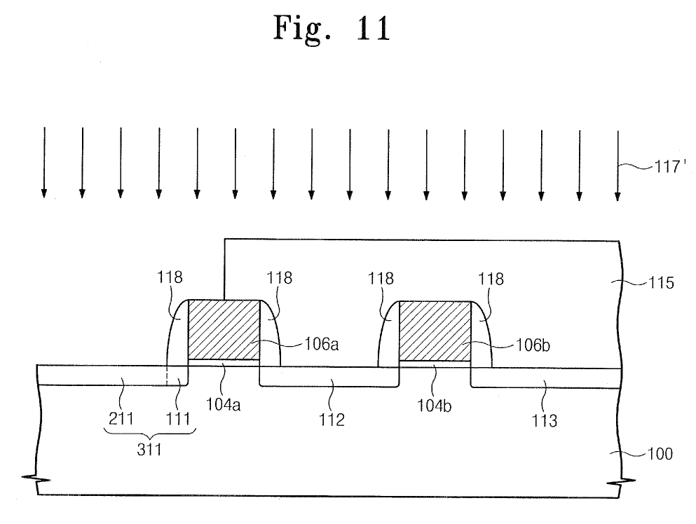

Referring to FIG. 11, the mask pattern 115 is then formed on the substrate 100. The mask pattern 115 covers the second and third low-concentration implant regions 112 and 113 and exposes the preliminary first low-concentration implant region 111. The portion of the preliminary first low-concentration implant region 111 adjacent to the access gate electrode 106a is covered by a gate spacer 118.

Next, a second ion implant 117 is performed using the mask pattern 115 as an implantation mask to implant the second N-type impurity ions into the active region. As a result, a first low-concentration implant region 311 is formed. As illustrated, the first low-concentration implant region 311 includes a first portion 111 and a second portion 211. The first portion 111 is located under the gate spacer 118 and includes the first N-type impurity while the second portion 211 is exposed by the gate spacer 118 and includes the first and second N-type impurities. In one embodiment, the dose quantity of the second N-type impurities implanted during the second ion implant 117′ may be more than the dose quantity of the second ion implant 117 previously described with respect to FIG. 7.

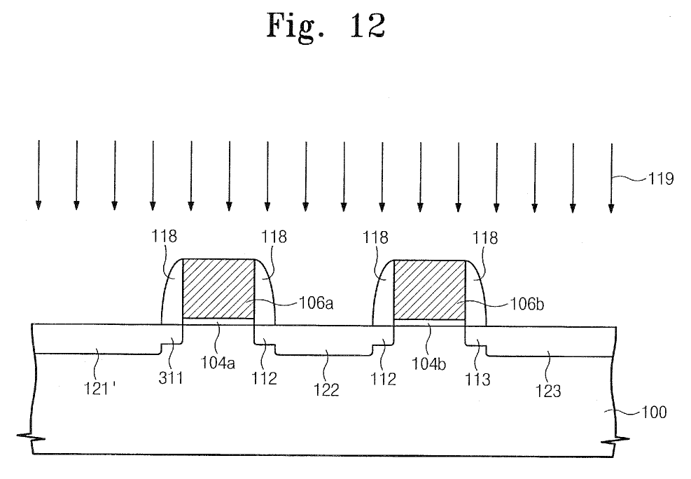

Referring to FIG. 12, the mask pattern 115 is removed and the gate electrodes 106a and 106b and gate spacer 118 are used as an implantation mask during the third ion implant 119. As a result of the third ion implant 119, the first, second, and third high-concentration implant regions 121′, 112 and 123 are formed. The concentration of second N-type impurity within the first high-concentration implant region 121′ may be higher than that of the first high-concentration implant region 121 previously discussed with respect to FIG. 8.

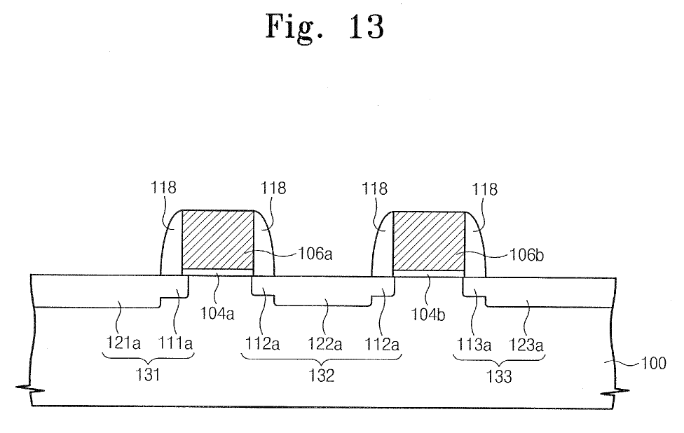

Referring to FIG. 13, the impurity activation process is performed as described above to form the first, second and third impurity regions 131, 132 and 133.

In the method of forming the first impurity region 131 as described with reference to FIGS. 10 to 13, the dose of the second N-type impurity ions of the second ion implant 117 and/or the temperature and/or process time of the impurity activation process may be adjusted to diffuse the second N-type impurities from the second portion 211 of the first low-concentration implant region 311 into the first portion 111 of the first low-concentration implant region 311.

As exemplarily described above, the first impurity region of the access transistor is connected to bit line and includes the first N-type impurity, having a relatively small diffusion coefficient, and the second N-type impurity, having a relatively large diffusion coefficient. As a result, the impurity concentration in a junction of the first impurity region decreases to minimize the hot carrier effect of the access transistor. Also, the volume increase of the first impurity region is limited by presence of the first N-type impurity, thereby controlling the short channel effect of the access transistor.

As exemplarily described above, the second impurity region of the access transistor includes only the first N-type impurity. Therefore, a short channel effect, which may be caused by the second impurity region, may be minimized. By minimizing both the hot carrier effect and the short channel effect, a highly integrated semiconductor device having a highly optimized access transistor may be realized.

As exemplarily described above, the second impurity region and the third impurity region are each used as drain/source of the driver transistor and are relatively free from hot carrier effects because they both include only the first N-type impurity having the relatively low diffusion coefficient. Therefore, the short channel effect of the driver transistor may be minimized.

Formed as described above, transistors included in the aforementioned semiconductor device may be optimized according to characteristics of each transistor to realize a highly integrated and high-performance semiconductor device.

Although the present invention has been described in connection with the embodiment of the present invention illustrated in the accompanying drawings, it is not limited thereto. It will be apparent to those skilled in the art that various substitution, modifications and changes may be thereto without departing from the scope and spirit of the invention.

What is claimed is:

1. A semiconductor device, comprising:
a substrate having an active region;
a first impurity region and a second impurity region in the active region;
an access gate insulating layer and an access gate electrode stacked on the active region between the first and second impurity regions;
an interlayer dielectric on the access gate electrode; and
a bit line on the interlayer dielectric and electrically connected to the first impurity region,
wherein the first impurity region includes a first N-type impurity and a second N-type impurity, the second impurity region includes the first N-type impurity and a diffusion coefficient of the first N-type impurity is smaller than a diffusion coefficient of the second N-type impurity.

2. The semiconductor device of claim 1, wherein the access gate electrode overlaps the first and second impurity regions, wherein
an area of overlap between the first impurity region and the access gate electrode is larger than an area of overlap between the second impurity region and the access gate electrode.

3. The semiconductor device of claim 1, further comprising:
a first junction including the first impurity region and a channel region under the access gate electrode; and
a second junction including the second impurity region and the channel region,
wherein an impurity concentration of a portion of the first impurity region adjacent to the first junction is smaller than an impurity concentration of a portion of the second impurity region adjacent to the second junction.

4. The semiconductor device of claim 1, further comprising a gate spacer on a sidewall of the access gate electrode.

5. The semiconductor device of claim 1, wherein the first impurity region comprises a first low-concentration region and a first high-concentration region and the second impurity region comprises a second low-concentration region and a second high-concentration region, wherein
the first low-concentration region is between the first high-concentration region and a channel region under the access gate electrode,
the second low-concentration region is between the second high-concentration region and the channel region, and
a concentration of first N-type impurity in the first high-concentration region is higher than a concentration of first N-type impurity in the first low-concentration region.

6. The semiconductor device of claim 1, further comprising:
a third impurity region in the active region; and
a driver gate insulating layer and a driver gate electrode on the active region between the second and third impurity regions,
wherein the second impurity region is operably proximate to the access gate electrode and the driver gate electrode.

7. The semiconductor device of claim 6, wherein the third impurity region includes the first N-type impurity.

8. The semiconductor device of claim 1, wherein the first N-type impurity is arsenic (As) and the second N-type impurity is phosphorus (P).

9. The semiconductor device of claim 6, further comprising:
a load transistor having a gate electrode and first and second source/drain regions,
wherein the first source/drain region is connected to a power line, the second source/drain region is connected to the second impurity region, and the gate electrode is connected to the driver gate electrode.

10. The semiconductor device of claim 1, wherein the access gate electrode is connected to a word line.

11. A method of forming a semiconductor device, the method comprising:
forming an access gate insulating layer and access gate electrode on an active region of a substrate;
forming a first impurity region and a second impurity region in the active region on either side of the access gate electrode;
forming an interlayer dielectric on the access gate electrode; and
forming a bit line on the interlayer dielectric, the bit line being electrically connected to the first impurity region,
wherein the first impurity region includes a first N-type impurity and a second N-type impurity, the second impurity region includes the first N-type impurity, and a diffusion coefficient of the first N-type impurity is smaller than a diffusion coefficient of the second N-type impurity.

12. The method of claim 11, wherein forming the first and the second impurity region comprises:
implanting the first N-type impurity into the active region at both sides of the access gate electrode in a first ion implant process to form a preliminary first implant region and a second implant region;
implanting the second N-type impurity into the preliminary first implant region in a second ion implant process to form a first implant region; and
activating the implanted first and second N-type impurities.

13. The method of claim 12, further comprising:
forming gate spacers on sidewalls of the access gate electrode after forming the first implant region; and
implanting the first N-type impurity into the first and second implant regions in a third ion implant process using the access gate electrode and the gate spacers as an implantation mask,
wherein a concentration of the first N-type impurity implanted in the third ion implant process is higher than a concentration of the first N-type impurity implanted in the first ion implant process.

14. The method of claim 12, further comprising forming a gate spacer on a sidewall of the access gate electrode before performing the second ion implant process.

15. The method of claim 14, further comprising:
implanting the first N-type impurity into the active region in a third ion implant process using the access gate electrode and gate spacer as an implantation mask,
wherein a concentration of the first N-type impurity implanted in the third ion implant process is higher than a concentration of the first N-type impurity implanted in the first ion implant process.

16. The method of claim 11, wherein the access gate electrode overlaps the first and second impurity regions, wherein
an area of overlap between the first impurity region and the access gate electrode is larger than an area of overlap between the second impurity region and the access gate electrode.

17. The method of claim 11, further comprising forming a channel region under the access gate electrode, wherein a first junction includes the first impurity region and the channel region; and a second junction includes the second impurity region and the channel region,
wherein an impurity concentration of a portion of the first impurity region adjacent to the first junction is smaller than an impurity concentration of a portion of the second impurity region adjacent to the second junction.

18. The method of claim 11, wherein the first N-type impurity is arsenic (As) and the second N-type impurity is phosphorus (P).

19. The method of claim 11, further comprising:
forming a driver gate insulating layer and a driver gate electrode on the active region; and
forming a third impurity region in the active region,
wherein the second impurity region is operably proximate to the access gate electrode and the driver gate electrode and the driver gate electrode is between the second impurity region and the third impurity region.

20. The method of claim 19, wherein the third impurity region includes the first N-type impurity.
